(19) United States
(12) Patent Application Publication
(10) Pub. No.: US 2021/0373616 A1
(43) Pub. Date: Dec. 2, 2021

(54) EXPANSION CARD ASSEMBLY AND EXPANSION CARD CAGE

(71) Applicants: INVENTEC (PUDONG) TECHNOLOGY CORPORATION, Shanghai (CN); INVENTEC CORPORATION, Taipei City (TW)

(72) Inventors: Zhifa CHEN, Shanghai City (CN); Sheng GUO, Shanghai City (CN)

(73) Assignees: INVENTEC (PUDONG) TECHNOLOGY CORPORATION, Shanghai (CN); INVENTEC CORPORATION, Taipei City (TW)

(21) Appl. No.: 16/903,197

(22) Filed: Jun. 16, 2020

(30) Foreign Application Priority Data
May 29, 2020 (CN) 202010471962.0

(51) Int. Cl. G06F 1/18; H05K 7/14

(52) U.S. Cl. CPC G06F 1/185; H05K 7/14

(57) ABSTRACT

The disclosure provides an expansion card cage including a cage, a latch and a fastener. The cage includes a back plate, a first mount plate, and a second mount plate. The back plate has two surfaces opposite to each other and two openings. The first mount plate and the second mount plate respectively protrude from the two surfaces of the back plate. The first mount plate is configured for an installation of a riser card configured for an insertion of an expansion card. The openings of the back plate are configured to expose the expansion card. The second mount plate has a fixation hole. The latch has a through hole. The fastener is disposed through the through hole of the latch and fixed in the fixation hole of the second mount plate so as to force the latch to press against a tab portion of the expansion card.

### CROSS-REFERENCE TO RELATED APPLICATIONS

This non-provisional application claims priority under 35 U.S.C. § 119(a) on Patent Application No(s). 202010471962.0 filed in China on May 29, 2020, the entire contents of which are hereby incorporated by reference.

### BACKGROUND OF THE INVENTION

### Technical Field of the Invention

The disclosure related to an expansion card assembly and an expansion card cage, more particularly to an expansion card assembly and an expansion card cage having a latch.

### Description of the Related Art

As technology develops and progresses, electronic devices are improved towards the trend of high performance and small size and integration. In other words, electronic devices now are required to be lightweight, miniaturized, and expandable.

Due to the size reduction of the electronic devices, the internal space is very limited, not to mention there is enough space available for the installation/removal of storage devices or expansion cards (e.g., PCIe cards). In a typical electronic device, the storage devices or the expansion cards will be fixed onto a fixation cage via screws, and the fixation cage is fixed to the casing of the electronic device via screws, such that the storage devices and the expansion cards can be firmly fixed in the electronic device.

However, the screwing processes of the storage device or the expansion cards and the fixation cage involve alignment of screws and screw holes, which is time-consuming and troublesome. And user often accidentally drop the screw and thus resulting in screw missing. In addition, screws may be improperly screwed to cause damage to the screw holes. The above are just a few problems caused by the usage of screws.

### SUMMARY OF THE INVENTION

The disclosure provides an expansion card assembly and an expansion card cage, which is capable of using a less number of screws for fixing the expansion cards in shorter time.

One embodiment of the disclosure provides an expansion card cage. The expansion card cage is configured to accommodate at least one expansion card. The expansion card cage includes a cage, a latch and a fastener. The cage includes a back plate, a first mount plate, and a second mount plate. The back plate has two surfaces opposite to each other and at least two openings penetrating through the two surfaces of the back plate. The first mount plate and the second mount plate respectively protrude from the two surfaces of the back plate. The first mount plate is configured for an installation of a riser card which is configured for an insertion of the expansion card. The openings of the back plate are configured to expose the expansion card. The second mount plate has a fixation hole. The latch has a through hole. The fastener is disposed through the through hole of the latch and fixed in the fixation hole of the second mount plate so as to force the latch to press against a tab portion of the expansion card.

Another embodiment of the disclosure provides an expansion card assembly. The expansion card assembly includes an expansion card cage, a riser card and at least one expansion card. The expansion card cage includes a cage, a latch and a fastener. The cage includes a back plate, a first mount plate and a second mount plate. The back plate has two surfaces opposite to each other and at least two opening penetrating through the two surfaces of the back plate. The first mount plate and the second mount plate respectively protrude from the two surfaces of the back plate, and the second mount plate has a fixation hole and at least one recess portion. The latch has a through hole and at least one protrusion portion. The fastener is disposed through the through hole of the latch and fixed in the fixation hole of the second mount plate so as to force the protrusion portion of the latch to press against the recess portion of the second mount plate. The riser card is installed on the first mount plate. The expansion card is installed on the riser card. The openings of the back plate expose the expansion card, and the protrusion portion of the latch presses against a tab portion of the expansion card.

According to the expansion card assembly and the expansion card cage as discussed above, the latch and the second mount plate can together clamp all of the expansion cards by screwing one fastener into the second mount plate. Therefore, the fixation of the expansion cards to the cage can be completed merely by screwing one fastener, which is simple and easy and helps to improve the assembly efficiency.

### BRIEF DESCRIPTION OF THE DRAWINGS

The present disclosure will become more fully understood from the detailed description given hereinbelow and the accompanying drawings which are given by way of illustration only and thus are not limitative to the present disclosure and wherein:

FIG. 1 is a perspective view of an expansion card assembly according to one embodiment of the disclosure;

FIG. 2 is an exploded view of the expansion card assembly in FIG. 1; and

FIG. 3 is a perspective view of the expansion card assembly in FIG. 1 when a latch is not yet pressing against a second mount plate.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the following embodiments are disclosed by the figures, and some practical details are described in the following paragraphs, but the present disclosure is not limited thereto. Furthermore, for the purpose of illustration, some of the structures and components in the figures are simplified, and wires, reference lines or buses are omitted in some of the figures.

Moreover, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

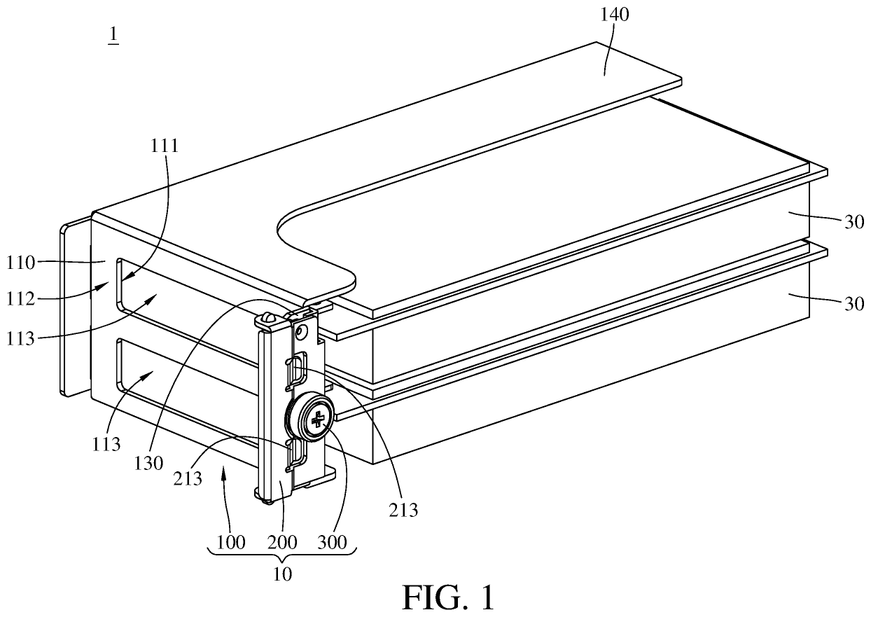

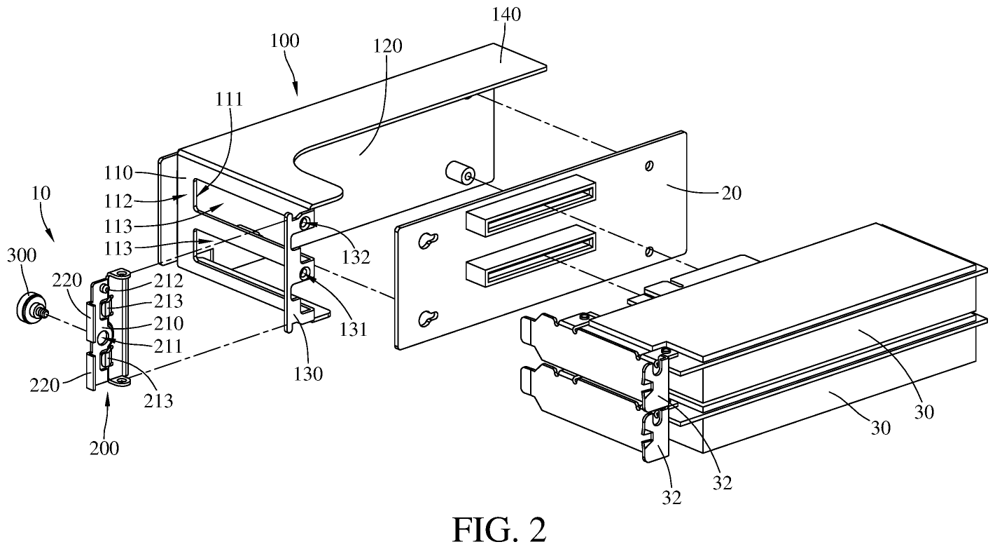

Referring to FIGS. 1 to 3, there are shown a perspective view of an expansion card assembly 1 according to one embodiment of the disclosure, an exploded view of the expansion card assembly 1 in FIG. 1, and a perspective view of the expansion card assembly 1 in FIG. 1 when a latch 200 is not yet pressing against a second mount plate 130.

In this embodiment, the expansion card assembly 1 includes an expansion card cage 10, a riser card 20, and a plurality of expansion cards 30. The expansion card cage 10 includes a cage 100, the latch 200, and a fastener 300.

The cage 100 includes a back plate 110, a first mount plate 120, and a second mount plate 130. The back plate 110 has two surfaces 111 and 112 opposite to each other and two openings 113 penetrating the surfaces 111 and 112 of the back plate 110. The first mount plate 120 and the second mount plate 130 respectively protrude from the surfaces 111 and 112 of the back plate 110. The first mount plate 120 is configured for the placement of the riser card 20. The riser card 20 is configured for the insertions of the expansion cards 30. The two openings 113 of the back plate 110 expose the expansion cards 30 accommodated in the cage 100. The second mount plate 130 has a fixation hole 131 and at least one recess portion 132.

In this embodiment, the cage 100 may further include a cover plate 140. The cover plate 140 is connected to the back plate 110 and the first mount plate 120. The cover plate 140 is configured to cover a side of the expansion card 30.

The latch 200 is pivotably disposed on the second mount plate 130, and the latch 200 has a through hole 211 and a protrusion portion 212. The fastener 300 is, for example, a thumb screw. The fastener 300 is disposed through the through hole 211 of the latch 200 and screwed into the fixation hole 131 so as to force the protrusion 212 of the latch 200 to press against the recess portion 132 of the second mount plate 130.

In this embodiment, the fastener 300 is not restricted to be the thumb screw; in some other embodiments, the fastener may be another suitable screw that can be driven by a hand tool (e.g., a flat blade screwdriver, a Phillips screwdriver or another-typed screwdriver).

In this embodiment, the latch 200 includes a plate portion 210 and two positioning portions 220. A side of the plate portion 210 is pivotably disposed on the second mount plate 130. The positioning portions 220 are connected to another side of the plate portions 210. When the protrusion portion 212 of the latch 200 press against the recess portion 132 of the second mount plate 130, the positioning portions 220 protrude towards the first mount plate 120, the plate portion 210 is configured to press against sides of tab portions 32 of the expansion cards 30 away from the second mount plate 130, and the positioning portions 220 are respectively configured to be located at sides of the tab portions 32 of the expansion cards 30 away from the back plate 110.

In this embodiment, the plate portion 210 may further have two elastic portions 213. When the protrusion portion 212 of the latch 200 presses against the recess portion 132 of the second mount plate 130, the elastic portions 213 respectively press against the tab portions 32 of the expansion cards 30.

In this embodiment, the quantities of the positioning portions 220 and the elastic portions 213 are not restricted to be two; in some other embodiments, the latch may include one or more than two positioning portions, and the plate portion of the latch may include one or more than two elastic portions.

The riser card 20 is installed on the first mount plate 120. The expansion cards 30 are installed on the riser card 20. The openings 113 of the back plate 110 respectively expose the expansion cards 30. When the fastener 300 is disposed through the through hole 211 of the latch 200 and screwed into the fixation hole 131 of the second mount plate 130, the fastener 300 and the protrusion portion 212 of the latch 200 respectively press against the tab portions 32 of the expansion cards 30.

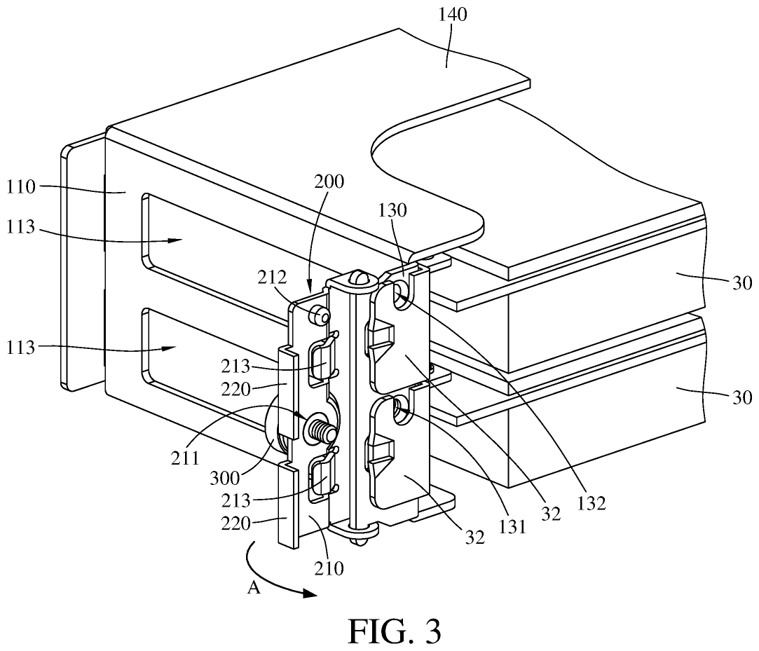

Regarding the steps of installing the riser card 20 and the expansion cards 30, as shown in FIG. 3, the riser card 20 may be firstly installed on the first mount plate 120, and then the expansion cards 30 may be installed on the riser card 20. By doing so, the tab portions 32 of the expansion cards 30 are in contact with the second mount plate 130 of the cage 100. Then, the latch 200 is pivoted along a direction A (as shown in FIG. 1) so that the fastener 300 is allowed to be screwed into the fixation hole 131 of the second mount plate 130. As such, the tab portions 32 of the expansion cards 30 are partially located between and clamped by the latch 200 and the second mount plate 130, and the positioning portions 220 of the latch respectively contacts with another parts of the tab portions 32 of the expansion cards 30 so as to limit the expansion cards 30. As a result, the fixation of the expansion cards 30 to the cage 100 can be completed merely by screwing one fastener 300, which is simple and easy and helps to improve the assembly efficiency.

In this embodiment, the latch 200 is not restricted to be pivotably disposed on the second mount plate 130; in some other embodiments; the latch may be fixed to the second mount plate in a non-pivotable manner.

In this embodiment, the quantities of the openings 113 and the expansion cards 30 are not restricted to be two; in some other embodiments, the back plate may have more than two openings, and the expansion card cage may be able to accommodate more than two expansion cards.

According to the expansion card assembly and the expansion card cage as discussed above, the latch and the second mount plate can together clamp all of the expansion cards by screwing one fastener into the second mount plate. Therefore, the fixation of the expansion cards to the cage can be completed merely by screwing one fastener, which is simple and easy and helps to improve the assembly efficiency.

The embodiments were chosen and described in order to best explain the principles of the disclosure and its practical applications, to thereby enable others skilled in the art to best utilize the disclosure and various embodiments with various modifications as are suited to the particular use contemplated. It is intended that the scope of the disclosure be defined by the following claims and their equivalents.

What is claimed is:

1. An expansion card cage, configured to accommodate at least one expansion card, comprising:
a cage, comprising a back plate, a first mount plate, and a second mount plate, wherein the back plate has two surfaces opposite to each other and at least two openings penetrating through the two surfaces of the back plate, the first mount plate and the second mount plate respectively protrude from the two surfaces of the back plate, the first mount plate is configured for an installation of a riser card which is configured for an insertion of the at least one expansion card, the at least two openings of the back plate are configured to expose the at least one expansion card, and the second mount plate has a fixation hole;
a latch, having a through hole; and
a fastener, disposed through the through hole of the latch and fixed in the fixation hole of the second mount plate so as to force the latch to press against a tab portion of the at least one expansion card.

2. The expansion card cage according to claim 1, wherein the latch is pivotably disposed on the second mount plate.

3. The expansion card cage according to claim 2, wherein the second mount plate has at least one recess portion, and the latch has at least one protrusion portion, the fastener is disposed through the through hole of the latch and fixed in the fixation hole of the second mount plate so as to force the at least one protrusion portion to press against the at least one recess portion of the second mount plate and the tab portion of the at least one expansion card, the latch comprises a plate portion and at least one positioning portion, a side of the plate portion is pivotably disposed on the second mount plate, the at least one positioning portion is connected to another side of the plate portion; when the at least one protrusion portion of the latch presses against the at least one recess portion of the second mount plate, the at least one positioning portion protrudes towards the first mount plate, the plate portion is configured to press against a side of the tab portion of the at least one expansion card away from the second mount plate, and the at least one positioning portion is configured to be located at a side of the tab portion of the at least one expansion card away from the back plate.

4. The expansion card cage according to claim 3, wherein the quantity of the at least one positioning portion is two, one of the positioning portions is configured to be located at the side of the tab portion of the at least one expansion card away from the back plate.

5. The expansion card cage according to claim 3, wherein the plate portion has at least one elastic portion, the at least one elastic portion is configured to press against the tab portion of the at least one expansion card.

6. The expansion card cage according to claim 5, wherein the quantity of the at least one elastic portion is two, one of the elastic portions is configured to press against the tab portion of the at least one expansion card.

7. The expansion card cage according to claim 1, wherein the fastener is a screw.

8. The expansion card cage according to claim 7, wherein the fastener is a thumb screw.

9. The expansion card cage according to claim 1, wherein the cage further comprises a cover plate, the cover plate is connected to the back plate and the first mount plate, and the cover plate is configured to cover a side of the at least one expansion card.

10. An expansion card assembly, comprising:
an expansion card cage, comprising:
a cage, comprising a back plate, a first mount plate and a second mount plate, wherein the back plate has two surfaces opposite to each other and at least two opening penetrating through the two surfaces of the back plate, the first mount plate and the second mount plate respectively protrude from the two surfaces of the back plate, and the second mount plate has a fixation hole and at least one recess portion;
a latch, having a through hole and at least one protrusion portion; and
a fastener, disposed through the through hole of the latch and fixed in the fixation hole of the second mount plate so as to force the at least one protrusion portion of the latch to press against the at least one recess portion of the second mount plate;
a riser card, installed on the first mount plate; and
at least one expansion card, installed on the riser card, wherein the at least two openings of the back plate expose the at least one expansion card, and the at least one protrusion portion of the latch presses against a tab portion of the at least one expansion card.
